(19) United States
(12) Patent Application Publication
(10) Pub. No.: US 2013/0010226 A1
(43) Pub. Date: Jan. 10, 2013

(54) LED PACKAGING STRUCTURE AND LIQUID CRYSTAL DISPLAY

(75) Inventors: Kuang-Yao Chang, Guangdong (CN); Weiwei Zheng, Guangdong (CN)

(73) Assignee: Shenzhen China Star Optoelectronics Technology Co. Ltd., Shenzhen, Guangdong (CN)

(21) Appl. No.: 13/375,229

(22) PCT Filed: Jul. 9, 2011
(86) PCT No.: PCT/CN2011/077013

§ 371 Date: Nov. 30, 2011

(51) Int. Cl. G02F 1/1335; H01L 33/60

(52) U.S. Cl. 349/61; 257/98; 257/E33.058; 257/E33.072

(57) ABSTRACT

An LED packaging structure includes a casing, an LED chip, and a lead frame arranged in the casing, The lead frame includes a bottom portion, and a first metal side wall and a second metal side wall respectively located on two sides of said bottom portion. The LED chip is arranged on the bottom portion. Plastic layers with high reflectivity are respectively disposed on surfaces of the first metal side wall and the second metal side wall are provided with and are extended towards the direction far away from the bottom portion and joint with the casing. The LED packaging structure of the present disclosure not only provides a longer path for the moisture to permeate the inside of the LED packaging structure, but also reduces the loss of the luminous flux due to light emitted from the LED chip irradiating on the metal bracket.

### BACKGROUND

1. Technical Field

The present disclosure relates to the field of liquid crystal display, in particular to an LED packaging structure of a backlight module.

2. Description of Related Art

LED (Light Emitting Diode) is a common light source, which has the advantages of low power consumption, long service life, etc. Thus, LEDS are widely applied to the fields of lighting and liquid crystal display etc. Wherein, the LED packaging structure exerts profound significance for improving the light emission and heat dissipation.

As is shown in FIG. 1, which is the schematic diagram showing the LED packaging structure with the lead frame having the plane structure in the prior art. The LED packaging structure 10 includes a casing 13, a lead frame 12 arranged in the casing 13 and an LED chip 11 located on a surface of the lead frame 12. The lead frame 12 includes two metal electrodes 12a and 12b disconnected from each other, and the LED chip 11 is arranged on the metal electrode 12b of the lead frame 12 insulatingly. A positive electrode and a negative electrode of the LED chip 11 are correspondingly connected to the metal electrodes 12a and 12b of the lead frame 12 through two metal leads 14, respectively. The casing 13 is used for sealing the LED chip 11. However, in this LED packaging structure, the interface between the casing 13 and the lead frame 12 cannot be sealed effectively, and a path of the external moisture arriving to the sealing space is shorter. Therefore, the external moisture is easy to permeate into the sealed LED space along the path pointed by the arrow of the dotted line AA′ and the path pointed by the arrow of the dotted line BB′ shown in FIG. 1, which affects the property of the LED packaging products, such as the vulcanization of the metal electrode etc. and further reduces the confidence degree of the product.

Additionally, the sealing space defined by the casing 13 and the lead frame 12 is filled with transparent resin (not shown in the FIG).

As shown in FIG. 2, which is the schematic diagram of the LED packaging structure with the lead frame having a concave in the prior art. The LED packaging structure 20 includes a casing 23, a lead frame 22 which is arranged into the housing of the casing 23, an LED chip 21 which is located on the surface of the concave of the lead frame 22, and a transparent resin (not shown in the FIG). The lead frame 22 includes two metal electrodes 22a and 22b, which are disconnected from each other. The LED chip 21 is arranged on the metal electrode 22a of the lead frame 22 insulatively. A positive electrode and a negative electrode of the LED chip 21 are connected to the corresponding two metal electrodes 22a and 22b of the lead frame 22 through two metal leads 24, respectively. The casing 23 is used for sealing the LED chip 21, and the casing 23 integrates with the lead frame 22 to define a sealing space. The sealing space is filled with the transparent resin. However, in this LED packaging structure with the lead frame 22 having the concave, the light emitted from the LED chip 21 directly irradiate on the metal side wall of the two metal electrodes 22a and 22b formed by the concave of the lead frame 22. The reflectivity of metal is low and often metal absorbs partial light, so that the luminous flux emitted from the LED packaging structure is low. In addition, compared with the LED packaging structure shown in FIG. 1, although the path of the external moisture arrived into the sealing space is lengthened, the path of the external moisture of this LED packaging structure is simpler and the length of the path is insufficient. The external moisture can still be permeated into the LED space via the path pointed by the dotted line CC′ arrow and the path pointed by the dotted line DD′ arrow shown in FIG. 2, which influences the property of the packaging product.

### SUMMARY

In order to solve the problem on the property of the LED package product influenced by the external moisture permeated into the packaging space of the LED chip in the LED packaging structure in the prior art, the present disclosure provides a n LED packaging structure, includes an LED chip, a lead frame and a casing. Said lead frame is arranged in said casing, said lead frame includes a first metal side wall, a second metal side wall and a bottom portion. Said first metal side wall and said second metal side wall are respectively located on the two sides of said bottom portion. Said LED chip is arranged on said bottom portion. The surfaces of said first metal side wall and said second metal side wall are provided with plastic layers with high reflectivity, and said plastic layers are extended towards the direction far away from said bottom portion along the surfaces of said first metal side wall and said second metal side wall and joint with said casing. Said casing is made of plastics. Said casing and said plastic layer with high reflectivity arranged on the surfaces of said first metal side wall and said second metal side wall are integrally molded

Preferably, said plastic layers with high reflectivity arranged on the surfaces of the first metal side wall and the second metal side wall are polyphthalamide layers.

Preferably, said casing is made of polyphthalamide materials.

Preferably, said plastic layers with high reflectivity arranged between the surfaces of the first metal side wall and the second metal side wall are polyimide layers.

Preferably, said casing is made of polyimide materials.

Preferably, said lead frame includes a first metal electrode and a second metal electrode. Said first metal electrode and said second metal electrode are disconnected from each other and are respectively connected to a positive electrode and a negative electrode of an external power supply. Moreover, said first metal electrode and said second metal electrode are correspondingly connected to a positive electrode and a negative electrode of said LED chip through two metal leads.

Preferably, said first metal electrode and said second metal electrode are winding-shaped, respectively.

Preferably, said casing and said bottom portion of said lead frame cooperate with each other to define a sealing space, and said sealing space is filled with transparent resin.

Preferably, a side surface of said casing irradiated by light emitted from the LED chip is provided with a metal coating layer with high reflectivity.

The present disclosure further provides an LED packaging structure including an LED chip, a lead frame and a casing. Said lead frame is arranged in said casing, said lead frame comprises a first metal side wall, a second metal side wall and a bottom portion. Said first metal side wall and said second metal side wall are respectively located on the two sides of said bottom portion; said LED chip is arranged on said bottom portion. Surfaces of said first metal side wall and said second metal side wall are provided with plastic layers with high reflectivity, and said plastic layers are extended towards the direction far away from said bottom portion along the surfaces of said first metal side wall and said second metal side wall and are jointed with said casing.

Preferably, said casing is made of plastics with high reflectivity, and said casing and said plastic layer with high reflectivity arranged on the surfaces of said first metal side wall and said second metal side wall are integrally molded.

Preferably, said plastic layers with high reflectivity arranged on the surfaces of the first metal side wall and the second metal side wall are polyphthalamide layers.

Preferably, said casing is made of polyphthalamide materials.

Preferably, said lead frame includes a first metal electrode and a second metal electrode, said first metal electrode and said second metal electrode are disconnected from each other and are respectively connected to a positive electrode and a negative electrode of an external power supply. Moreover, said first metal electrode and said second metal electrode are correspondingly connected to a positive electrode and a negative electrode of said LED chip through two metal leads.

Preferably, said first metal electrode and said second metal electrode are winding-shaped, respectively.

Preferably, said casing and said bottom portion of said lead frame cooperate with each other to define a sealing space, and said sealing space is filled with transparent resin.

Preferably, a side surface of said casing irradiated by the light emitted from the LED chip is provided with a metal coating layer with high reflectivity.

Preferably, said plastic layers with high reflectivity arranged on the surfaces of the first metal side wall and the second metal side wall are polyimide layers.

Preferably, said first metal side wall, said second metal side wall and said bottom portion cooperate with each other to define a groove, said groove is a round table shape, wherein said bottom portion is the upper bottom of the round table, the opening of said groove is the lower bottom of the round table; a length of the upper bottom of said round table is smaller than that of the lower bottom of said round table.

The present disclosure further provides a liquid crystal display, including a liquid crystal display panel and a backlight module. Said backlight module includes said LED packaging structure described above.

The LED packaging structure and the liquid crystal display of the present disclosure reduces the loss of the luminous flux of the LED due to the direct irradiation on the metal side wall through the plastic layers with high reflectivity arranged on the metal side wall of the lead frame.

### BRIEF DESCRIPTION OF THE DRAWINGS

FIG. 1 is a schematic diagram showing the LED packaging structure with the lead frame having the plane structure in prior art.

FIG. 2 is a schematic diagram of the LED packaging structure with the lead frame having a concave in the prior art.

FIG. 3 is the schematic diagram of the preferable exemplary embodiment of the LED packaging structure according to one embodiment of the present disclosure.

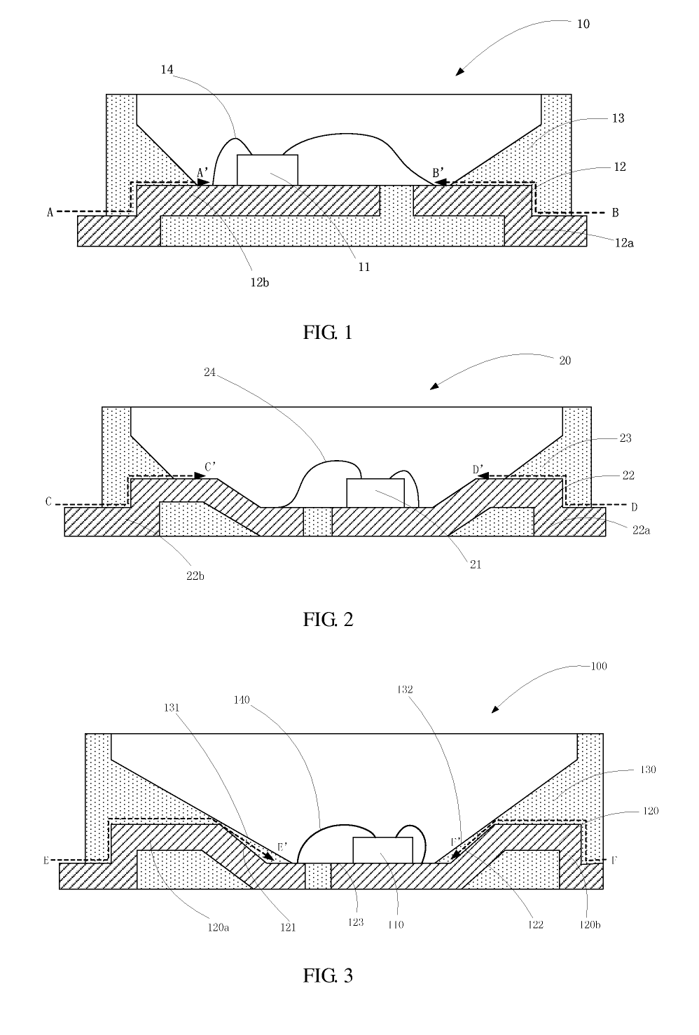

The purpose implementation, the function features and advantages of the invention will be further illustrated by integrating the exemplary embodiments and taking the attached drawings as references.

### DETAILED DESCRIPTION

The technical method for realizing the invention purpose will be illustrated in detail by integrating the attached drawings and the exemplary embodiments. It should be understood that the described exemplary embodiments herein are only used for illustrating this invention rather than limiting.

Referring to FIG. 3, an LED packaging structure 100 includes a casing 130, a lead frame 120 arranged in the casing 130, an LED chip 110 located on a surface of the lead frame 120, and a transparent resin (not shown in the FIG). The lead frame 120 includes a first metal electrode 120a and a second metal electrode 120b. Said first metal electrode 120a and said second metal electrode 120b are disconnected from each other and connected to a positive electrode and a negative electrode of an external power supply (not shown in the FIG), respectively. The first metal electrode 120a and the second metal electrode 120b are electrically connected with a positive electrode and a negative electrode of the LED chip 110 via two metal leads 140, respectively. The first metal electrode 120a and the second metal electrode 120b are respectively winding-shaped to allow the permeated path of the moisture to become flexural. As such, external moisture is prevented from permeating into the LED packaging cavity.

The lead frame 120 includes a first metal side wall 121, a second metal side wall 122 and a bottom portion 123. The first metal side wall 121, the second metal side wall 122 and the bottom portion 123 cooperate with each other to define a groove. The first metal side wall 121 and the second metal side wall 122 are respectively located at two sides of the bottom portion 123. The LED chip 110 is arranged on the bottom portion 123. The first metal side wall 121 is arranged on the first metal electrode 120a, and the second metal side wall 122 is arranged on the second metal electrode 120b. The bottom portion 123 is formed by one end of the first metal electrode 120a and one end of the second metal electrode 120b bending into a same plane and extending towards each other. The casing 130 is used for sealing the LED chip 110, which integrates with the bottom portion 123 of the lead frame 120 to define a sealing space. The sealing space is filled with the transparent resin.

Surfaces of the first metal side wall 121 and the second metal side wall 122 of the lead frame 120 are provided with plastic layers 131 and 132 with high reflectivity, and the plastic layers 131, 132 are extended towards the direction far away from the bottom portion 123 along the surfaces of the first metal side wall 121 and the second metal side wall 122 and joint with the casing 130. Therefore, as shown in FIG. 3, although the external moisture can still possibly enter the sealing space along the path pointed by the arrow of the dotted line EE′ and the path pointed by the arrow of the dotted line FF′, the path for said external moisture to arrive the sealing space of the LED packaging structure is longer and more flexural than that of the prior art. Therefore, it is more difficult for the external moisture to enter the sealing space. Additionally, it can effectively avoid the influence to the property of the LED chip when the external moisture permeates the sealing space, and improve the confidence degree of the LED packaging product.

Further, the casing 130 is made of plastics; preferably, the casing 130 is made of plastics with high reflectivity, and the casing 130 and the plastic layers 131, 132 with high reflectivity covered on the surfaces of the first metal side wall 121 and the second metal side wall 122 of the lead frame 120 are integrally molded, which can improve the sealing property of the sealing space of the LED packaging structure, effectively prevent the external moisture from entering, more effectively avoid the influence towards the property of the LED chip when the external moisture permeates the sealing space, and improve the confidence degree of the LED packaging product.

In one exemplary embodiment, the plastic layers 131, 132 with high reflectivity which are located on the surfaces of the first metal side wall 121 and the second metal side wall 122 of the lead frame 120 are made of Polyphthalamide (PPA) or polyimide.

Further, the casing 130 is also made of polyphthalamide materials. The casing 130 and the plastic layers 131, 132 are integrally molded, said plastic layer 131, 132 is made of polyphthalamide materials covered on the surfaces of the first metal side wall 121 and the second metal side wall 122 of the lead frame 120. The casing 130 and the plastic layers 131, 132 made of polyphthalamide can be integrally molded by common molding technology, such as the integral ejection molding, with which the manufacturing cost of the product can be reduced.

Therefore, compared with prior art, by arranging the plastic layers 131 and 132 with high reflectivity on the surfaces of the first metal side wall 121 and the second metal side wall 122 of the lead frame 120, the light emitted from the LED chip 110 is directly irradiated to the plastic layers 131 and 132 with high reflectivity and is reflected outside of the sealing space of the LED packaging structure, so that the loss of the luminous flux is reduced.

It is noted that the LED packing structure is not limited to the embodiment. In other embodiments, the first metal side wall 121, the second metal side wall 122 and the bottom portion 123 can define a groove of a round table shape. Wherein, said bottom portion 123 is an upper bottom of the round table, an opening of said groove is a lower bottom of the round table; a length of the upper bottom of said round table is smaller than that of the lower bottom of said round table to allow light to be easily emitted therefrom. In addition, the side surface of said casing irradiated by the light emitted from the LED chip is provided with a metal coating layer with high reflectivity, such as a silver coating layer.

Additionally, the present disclosure further provides a liquid crystal display, which includes a liquid crystal display panel and a backlight module. Said backlight module includes said LED packaging structure, which will not be described in detail here.

Any equivalent replacements made by the description and drawings of the invention, which are directly or indirectly applied to other related technical fields, should be included into the patent protection scope of the invention.

What is claimed is:

1. An LED packaging structure, comprising:
a casing;
a lead frame arranged in said casing; the lead frame comprising a first metal side wall, a second metal side wall and a bottom portion; said first metal side wall and said second metal side wall being respectively located on two sides of said bottom portion; and
an LED chip arranged on said bottom portion;
wherein surfaces of said first metal side wall and said second metal side wall are provided with plastic layers with high reflectivity, and said plastic layers are extended towards the direction far away from said bottom portion along the surfaces of said first metal side wall and said second metal side wall and joint with said casing;
said casing is made of plastics, the casing and said plastic layers with high reflectivity arranged on the surfaces of said first metal side wall and said second metal side wall are integrally molded.

2. The LED packaging structure according to claim 1, wherein said plastic layers with high reflectivity arranged on the surfaces of the first metal side wall and the second metal side wall are polyphthalamide layers.

3. The LED packaging structure according to claim 2, wherein said casing is made of polyphthalamide materials.

4. The LED packaging structure according to claim 1, wherein said plastic layers with high reflectivity arranged on the surfaces of the first metal side wall and the second metal side wall are polyimide layers.

5. The LED packaging structure according to claim 4, wherein said casing is made of polyimide materials.

6. The LED packaging structure according to claim 1, wherein said lead frame comprises a first metal electrode and a second metal electrode; said first metal electrode and said second metal electrode are disconnected from each other and are respectively connected to a positive electrode and a negative electrode of an external power supply; said first metal electrode and said second metal electrode are correspondingly connected to a positive electrode and a negative electrode of said LED chip through two metal leads.

7. The LED packaging structure according to claim 6, wherein said first metal electrode and said second metal electrode are winding-shaped, respectively.

8. The LED packaging structure according to claim 7, wherein said casing and said bottom portion of said lead frame cooperate with each other to define a sealing space, and the sealing space is filled with transparent resin.

9. The LED packaging structure according to claim 1, wherein a side surface of said casing irradiated by light emitted from the LED chip is provided with a metal coating layer with high reflectivity.

10. An LED packaging structure, comprising:
a casing;
a lead frame arranged in said casing, said lead frame comprising a first metal side wall, a second metal side wall and a bottom portion; said first metal side wall and said second metal side wall being respectively located on two sides of said bottom portion; and
an LED chip arranged on said bottom portion;
wherein the surfaces of said first metal side wall and said second metal side wall are provided with plastic layers with high reflectivity, and said plastic layers are extended towards the direction far away from said bottom portion along the surfaces of said first metal side wall and said second metal side wall and are jointed with said casing.

11. The LED packaging structure according to claim 10, wherein said casing is made of plastics with high reflectivity; and said casing and said plastic layers with high reflectivity arranged on the surfaces of said first metal side wall and said second metal side wall are integrally molded.

12. The LED packaging structure according to claim 11, wherein said plastic layers with high reflectivity arranged on the surfaces of the first metal side wall and the second metal side wall are polyphthalamide layers.

13. The LED packaging structure according to claim 12, characterized in that, said casing is made of polyphthalamide materials.

14. The LED packaging structure according to claim 10, wherein said lead frame comprises a first metal electrode and a second metal electrode; said first metal electrode and said second metal electrode are disconnected from each other and are respectively connected to a positive electrode and a negative electrode of an external power supply; said first metal electrode and said second metal electrode are correspondingly connected to a positive electrode and a negative electrode of said LED chip through two metal leads.

15. The LED packaging structure according to claim 14, wherein said first metal electrode and said second metal electrode are winding-shaped, respectively.

16. The LED packaging structure according to claim 10, wherein said casing and said bottom portion of said lead frame cooperate with each other to define a sealing space, and the sealing space is filled with transparent resin.

17. The LED packaging structure according to claim 16, wherein a side surface of said casing irradiated by light emitted from the LED chip is provided with a metal coating layer with high reflectivity.

18. The LED packaging structure according to claim 10, wherein said plastic layers with high reflectivity arranged on the surfaces of the first metal side wall and the second metal side wall are polyphthalamide layers.

19. The LED packaging structure according to claim 10, wherein said first metal side wall, said second metal side wall and said bottom portion cooperate with each other to define a groove, said groove is a round table shape, wherein said bottom portion is the upper bottom of the round table, the opening of said groove is the lower bottom of the round table; a length of the upper bottom of said round table is smaller than that of the lower bottom of said round table.

20. A liquid crystal display, comprising:
a liquid crystal display panel; and
a backlight module comprising an LED packaging structure, said LED packaging structure comprising:
a casing;
a lead frame arranged in the housing of said casing, said lead frame comprises a first metal side wall, a second metal side wall and a bottom portion; said first metal side wall and said second metal side wall being respectively located on two sides of said bottom portion; and
an LED chip arranged on said bottom portion;
wherein surfaces of said first metal side wall and said second metal side wall are provided with plastic layers with high reflectivity, and said plastic layers are extended towards the direction far away from said bottom portion along the surfaces of said first metal side wall and said second metal side wall and are jointed with said casing.
